(19) United States
(12) Patent Application Publication
(10) Pub. No.: US 2026/0192559 A1
(43) Pub. Date: Jul. 9, 2026

(54) DUMMY PANEL REMOVAL DEVICE AND DUMMY PANEL REMOVAL SYSTEM INCLUDING THE SAME

(71) Applicant: Samsung Display Co., LTD., Yongin-si (KR)

(72) Inventor: KANG-HYUK LEE, Yongin-si (KR)

(21) Appl. No.: 19/294,964

(22) Filed: Aug. 8, 2025

(30) Foreign Application Priority Data
Jan. 9, 2025 (KR) 10-2025-0003699

(51) Int. Cl. B32B 43/00

(52) U.S. Cl. CPC B32B 43/006; B32B 2457/20

(57) ABSTRACT

A dummy panel removal device includes: a dummy block including a first surface facing a first direction, wherein the first surface of the dummy block contacts a first side of a dummy panel; a grip portion positioned to face the dummy block and including a second surface facing the first surface of the dummy block with the dummy panel interposed between the dummy block and the grip portion; and a catching portion fixed to the dummy block between the dummy block and the grip portion. The catching portion includes a catching extension portion protruding more in the first direction than the first surface of the dummy block.

This application claims priority to Korean Patent Application No. 10-2025-0003699, filed on January 9, 2025, and all the benefits accruing therefrom under 35 U.S.C. §119, the content of which in its entirety is herein incorporated herein by reference.

### BACKGROUND

### Field

The present disclosure relates to a dummy panel removal device and a dummy panel removal system including the dummy panel removal device.

### Description of the Related Art

Electronic devices may be activated according to electrical signals. Electronic devices may include display devices for displaying images. Such display devices may include light emitting diodes, which may implement deep and vivid colors and provide wide viewing angles.

Display devices may include a display panel that visually displays or outputs information. The display panel may be formed on a mother substrate together with a dummy panel. The dummy panel, which is separated from the display panel, may be removed during a manufacturing process.

### SUMMARY

The present disclosure provides a dummy panel removal device and a dummy panel removal system including the dummy panel removal device that may easily remove dummy panels.

According to an embodiment, a dummy panel removal device includes: a dummy block including a first surface facing a first direction, where the first surface of the dummy block contacts a first side of a dummy panel; a grip portion positioned to face the dummy block and including a second surface facing the first surface of the dummy block with the dummy panel interposed between the dummy block and the grip portion; and a catching portion fixed to the dummy block between the dummy block and the grip portion. In such an embodiment, the catching portion includes a catching extension portion protruding more in the first direction than the first surface of the dummy block.

In an embodiment, the device may further include a body portion including the dummy block fixed to one side surface of the body portion.

In an embodiment, the body portion may accommodate a portion of the grip portion and a rotation axis, and provide driving force for pivoting the grip portion about the rotation axis.

In an embodiment, the dummy block may include: a block center portion extending in a second direction intersecting the first direction; and a first block extension portion and a second block extension portion extending in opposite directions along the first direction respectively from both opposing ends of the block center portion in the second direction, where the first surface of the dummy block may be at an end of the first block extension portion in the first direction.

In an embodiment, the grip portion may include: a first grip extension portion extending in a second direction intersecting the first direction; and a second grip extension portion extending in the first direction from an end of the first grip extension portion in the second direction.

In an embodiment, the second surface of the grip portion may be a surface of the first grip extension portion.

In an embodiment, in a state where the second surface of the grip portion faces the first surface of the dummy block with the dummy panel interposed between the dummy block and the grip portion, the first grip extension portion may cross over the catching extension portion in the second direction when viewed in a third direction intersecting both the first direction and the second direction.

In an embodiment, the catching portion may further include a catching center portion including a surface facing a second direction intersecting the first direction and fixed to the dummy block, and the catching extension portion may extend in the first direction from an end of the catching center portion in a third direction intersecting both the first direction and the second direction.

In an embodiment, the catching extension portion may include a pair of extensions extending in the first direction respectively from both opposing ends of the catching center portion in the third direction, and a distance between the pair of extensions in the third direction may be greater than a length of the grip portion in the third direction.

In an embodiment, the catching extension portion may include a protrusion protruding from the catching center portion toward the dummy block.

In an embodiment, a collision edge of the catching extension portion adjacent to the first surface of the dummy block may have a curved shape.

In an embodiment, the curved shape may be an arc shape.

In an embodiment, the first surface of the dummy block and the collision edge are spaced apart in a second direction intersecting the first direction, and a spacing distance between the first surface of the dummy block and the collision edge in the second direction may be equal to or less than one-fifth of a length of the first surface of the dummy block in the second direction.

In an embodiment, an anti-adhesion coating may be coated on the second surface of the grip portion.

In an embodiment, an anti-adhesion coating may be coated on the catching portion.

According to an embodiment, a dummy panel removal system includes: a plurality of dummy panel removal devices, where each of the plurality of dummy panel removal devices includes: a dummy block including a first surface facing a first direction, where the first surface of the dummy block contacts a first side of a dummy panel; a grip portion positioned to face the dummy block and including a second surface facing the first surface of the dummy block with the dummy panel interposed between the dummy block and the grip portion; and a catching portion fixed to the dummy block between the dummy block and the grip portion. In such an embodiment, the catching portion includes a catching extension portion protruding more in the first direction than the first surface of the dummy block, and the plurality of dummy panel removal devices are arranged along an extension direction of the dummy panel.

In an embodiment, in a state where the second surface of the grip portion faces the first surface of the dummy block with the dummy panel interposed between the dummy block and the grip portion, the grip portion may cross over the catching extension portion in a second direction intersecting the first direction when viewed in a third direction intersecting both the first direction and the second direction.

In an embodiment, the catching portion may further include a catching center portion including a surface facing a second direction intersecting the first direction and fixed to the dummy block, and the catching extension portion may extend in the first direction from an end of the catching center portion in a third direction intersecting both the first direction and the second direction.

In an embodiment, a collision edge of the catching extension portion adjacent to the first surface of the dummy block may have a curved shape.

In an embodiment, the first surface of the dummy block and the collision edge may be spaced apart in a second direction intersecting the first direction, and a spacing distance between the first surface of the dummy block and the collision edge in the second direction may be equal to or less than one-fifth of a length of the first surface in the second direction.

According to embodiments, a dummy panel may be easily removed from the dummy panel removal device.

### BRIEF DESCRIPTION OF THE DRAWINGS

FIG. 1 is a plan view illustrating a display panel and a dummy panel formed on a mother substrate.

FIG. 2 is a perspective view illustrating a display panel and a dummy panel placed on a stage.

FIG. 3 is a cross-sectional view taken along line III-III' of FIG. 2.

FIG. 4 is a view illustrating a dummy panel removal system according to an embodiment.

FIG. 5 is a view illustrating a dummy panel removal device according to an embodiment.

FIG. 6 is a cross-sectional view taken along line VI-VI' of FIG. 5.

FIG. 7 is a side view illustrating a pivot operation of the grip portion of a dummy panel removal device according to an embodiment.

FIG. 8 is a plan view illustrating a dummy panel in an elastically deformed state.

FIG. 9 is a view illustrating a state where the first grip extension portion and the dummy panel are adhered.

FIG. 10 is a view illustrating a process of transferring the dummy panel from the first grip extension portion to the catching extension portion.

FIG. 11 is a view illustrating a state where the dummy panel is adhered to the catching extension portion.

FIG. 12 is a side view illustrating a shape of the catching portion.

### DETAILED DESCRIPTION

Hereinafter, various embodiments will be described in detail with reference to the accompanying drawings to enable those skilled in the art to easily implement them. The present disclosure may be implemented in various different forms and is not limited to the embodiments described herein.

For clear explanation of the present disclosure, portions not related to the description have been omitted, and throughout the specification, like reference numerals denote like components.

Also, the size and thickness of each component shown in the drawings are arbitrarily shown for convenience of description, and thus the present disclosure is not necessarily limited to what is shown. In the drawings, the thickness of layers and regions is exaggerated for clarity. And in the drawings, for convenience of description, the thickness of some layers and regions is exaggerated.

In addition, when a part such as a layer, film, region, or plate is referred to as being "on" or "above" another part, it includes both the case where it is "directly on" the other part and the case where there is still another part in between. Conversely, when a part is referred to as being "directly on" another part, it means there is no other part in between. Also, being "on" or "above" the reference part means being located above or below the reference part, and does not necessarily mean being located in the direction opposite to gravity when referring to being "on" or "above."

Also, throughout the specification, when a part "includes" a component, this does not exclude other components unless specifically stated otherwise, but means that other components may be further included.

Also, throughout the specification, "in a plan view" means when the target portion is viewed from above, and "in a cross-sectional view" means when a vertical cross-section of the target portion is viewed from the side.

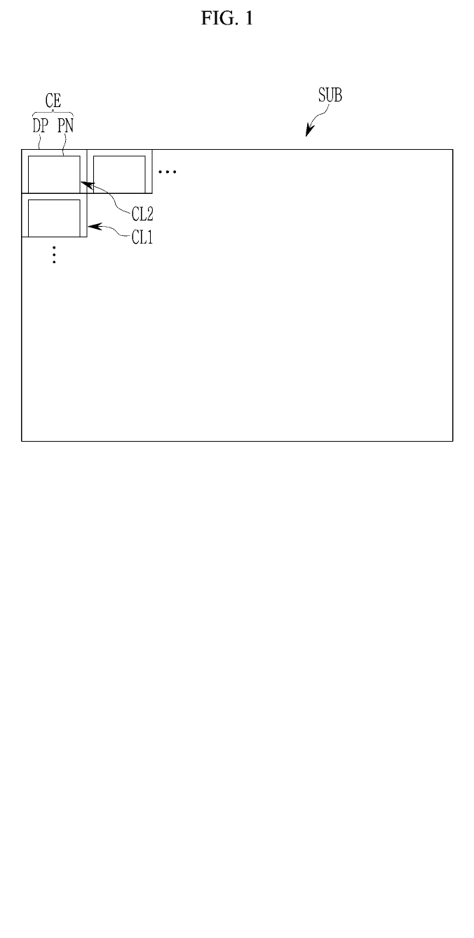

Hereinafter, an embodiment of a display panel and a dummy panel will be described with reference to FIG. 1. FIG. 1 is a plan view illustrating a display panel and a dummy panel formed on a mother substrate.

An embodiment of an electronic device including a display panel PN may provide visual information. An electronic device may be a device that performs various tasks using electricity. A display panel PN may be included in a display device, and the display device may be included in an electronic device. The electronic device may have functions of transmitting, storing, and computing information by processing or converting electrical signals. An electronic device including a display panel PN may be a smartphone, camera, tablet, laptop computer, monitor, television, smart watch, e-book reader, personal digital assistant (PDA), portable multimedia player (PMP), game console, or car navigation system.

The display panel PN may be formed together with the dummy panel DP on the mother substrate SUB. The display panel PN and the dummy panel DP may form or define one cell CE on the mother substrate SUB. A plurality of cells CE may be formed or defined on the mother substrate SUB. The plurality of cells CE on the mother substrate SUB may be arranged adjacent to each other. As the area of the mother substrate SUB increases, more cells CE may be formed on the mother substrate SUB.

In an embodiment, the mother substrate SUB may include a material having relatively high rigidity. In another embodiment, the mother substrate SUB may include a flexible material. Because the mother substrate SUB includes a flexible material, the mother substrate SUB may have flexible properties.

The display panel PN may be a device that receives electrical signals and displays images based on the electrical signals. The display panel PN may include conductive patterns, transistors, light-emitting materials, or the like.

The dummy panel DP may be adjacent to at least one side of the display panel PN. The dummy panel DP may include inspection patterns for inspecting the display panel PN. In an embodiment, for example, the dummy panel DP may include alignment inspection patterns for inspecting the alignment of conductive patterns included in the display panel PN.

In a manufacturing process of the electronic device, each of the plurality of cells CE may be separated along imaginary first cutting lines CL1. In an embodiment, for example, the first cutting lines CL1 may be imaginary lines along which laser is radiated to separate each cell CE.

One separated cell CE may include one display panel PN and one dummy panel DP, that is, each separated cell CE may include a single display panel PN and a single dummy panel DP. The separated cell CE may be placed on a stage. An imaginary second cutting line CL2 may be positioned or defined between one display panel PN and one dummy panel DP. The dummy panel DP may be separated from the display panel PN by laser irradiation along the imaginary second cutting line CL2.

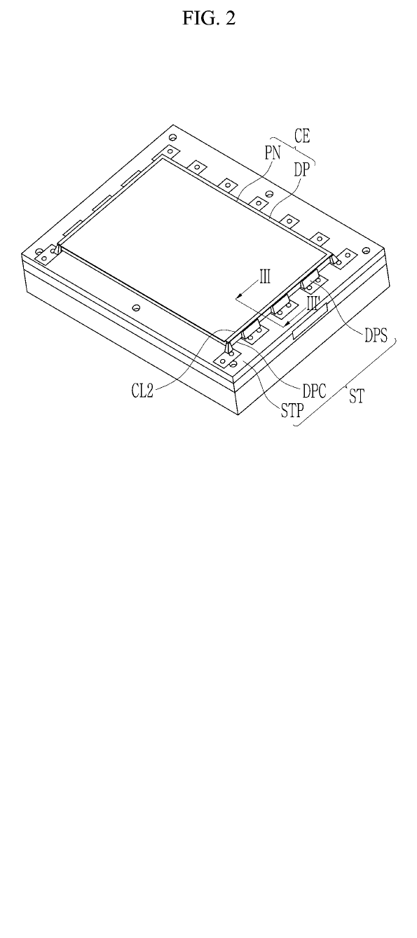

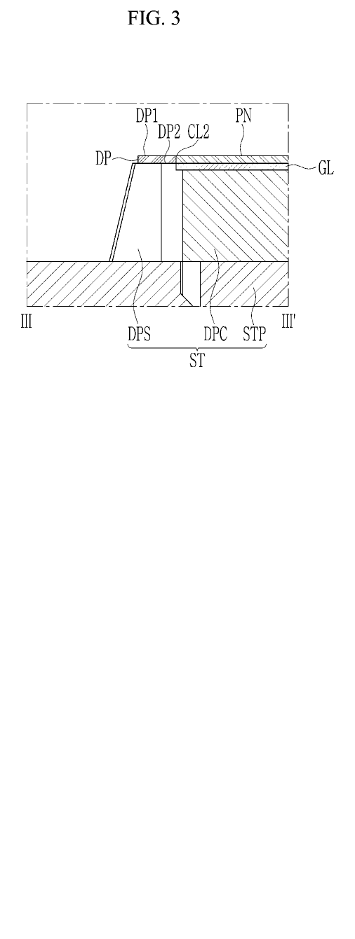

Hereinafter, an embodiment of the process of separating the display panel and the dummy panel will be described with reference to FIGS. 2 and 3. FIG. 2 is a perspective view illustrating a display panel and a dummy panel placed on a stage. FIG. 3 is a cross-sectional view taken along line III-III' of FIG. 2.

One cell CE separated along the first cutting line by laser irradiation may be placed on the stage ST.

The stage ST may include a flat portion STP, a convex portion DPC, and a dummy panel support portion DPS. The stage ST may support the separated cell CE to effectively prevent the separated cell CE from shaking.

The flat portion STP may serve as a support for the convex portion DPC and the dummy panel support portion DPS. The flat portion STP may include a flat surface. The convex portion DPC and the dummy panel support portion DPS may be placed on the flat portion STP. In an embodiment, for example, the flat portion STP may be rectangle in shape, that is, have a rectangular planar shape.

The convex portion DPC may be positioned at the center of the flat portion STP and may have an upwardly protruding shape. A glass GL may be placed on the convex portion DPC. A portion of the convex portion DPC in contact with the glass GL may have a flat shape.

The dummy panel support portion DPS may be positioned on the flat portion STP. The dummy panel support portion DPS may be provided in plurality. The plurality of dummy panel support portions DPS may be arranged along the periphery of the convex portion DPC. The plurality of dummy panel support portions DPS may be arranged spaced apart from each other to correspond to the shape of the dummy panel DP. The dummy panel DP may be placed on the dummy panel support portion DPS. A portion of the dummy panel support portion DPS in contact with the dummy panel DP may have a flat shape or a flat surface.

The glass GL may be placed on the convex portion DPC. The display panel PN may be placed on the glass GL. Also, an imaginary second cutting line CL2 corresponding to the boundary between the display panel PN and the dummy panel DP may be set on the glass GL. In an embodiment, for example, the imaginary second cutting line CL2 corresponding to the boundary between the display panel PN and the dummy panel DP may be defined by edges of the glass GL The display panel PN and the dummy panel DP may be separated by laser irradiation along the second cutting line CL2 while the display panel PN and the dummy panel DP are placed on the stage ST. The glass GL may be formed of a material that is not easily damaged or deformed by laser. One surface of the glass in contact with the display panel PN may have a flat shape.

The dummy panel DP may include a first side (or first surface) DP1 formed on the side opposite to the stage ST and a second side (or second surface) DP2 formed on the stage ST side. The second side DP2 of the dummy panel DP may be a surface opposite to the first side DP1 of the dummy panel DP. Referring to FIG. 3, the first side DP1 of the dummy panel DP may be an upper surface thereof, and the second side DP2 of the dummy panel DP may be a lower surface thereof. The second side DP2 of the dummy panel DP may be in contact with the dummy panel support portion DPS. An adhesive may be applied to the second side DP2 of the dummy panel DP. That is, the second side DP2 of the dummy panel DP may have adhesiveness. Due to the second side DP2 of the dummy panel DP having adhesiveness, the display panel PN and the dummy panel DP may be effectively fixed without shaking onto the stage ST.

After separating the display panel PN and the dummy panel DP by radiating laser along the second cutting line CL2, the dummy panel DP may be removed from the stage ST. The separated dummy panel DP may be removed using a dummy panel removal device. The dummy panel DP detached from the dummy panel support portion DPS by the dummy panel removal device may be placed or stored in a dummy storage portion for disposal.

The dummy panel removal device may be positioned between different dummy panel support portions DPS and grip the dummy panel DP. The dummy panel removal device may detach the dummy panel DP from the dummy panel support portion DPS by moving in a direction opposite to the stage ST while gripping the dummy panel DP. Referring to FIG. 3, the dummy panel removal device may detach the dummy panel DP from the dummy panel support portion DPS by rising upward while gripping the dummy panel DP.

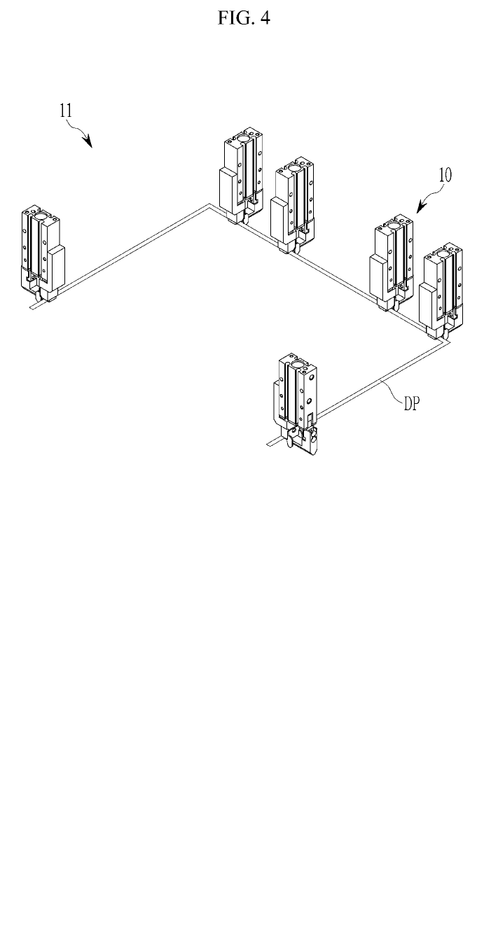

Hereinafter, a dummy panel removal system according to an embodiment that may easily remove dummy panels will be described with reference to FIG. 4. FIG. 4 is a view illustrating a dummy panel removal system according to an embodiment.

In an embodiment, a plurality of dummy panel removal devices 10 may be arranged according to the shape of the dummy panel DP. The dummy panel DP may be placed on the dummy panel support portion DPS. The plurality of dummy panel removal devices 10 may form or collectively define a dummy panel removal system 11 by being arranged along the extension direction of the dummy panel DP.

The plurality of dummy panel removal devices 10 of the dummy panel removal system 11 may grip the dummy panel DP. The plurality of dummy panel removal devices 10 may be arranged spaced apart from each other. The plurality of dummy panel removal devices 10 arranged spaced apart from each other may grip different portions of the dummy panel DP.

The plurality of dummy panel removal devices 10 included in the dummy panel removal system 11 may sequentially move in a direction opposite to the stage after gripping the dummy panel DP. In an embodiment, for example, the dummy panel removal devices 10 closer to the end portion of the dummy panel DP may move first in the direction opposite to the stage. This enables stable detachment of the dummy panel DP from the dummy panel support portion. Also, the plurality of dummy panel removal devices 10 included in the dummy panel removal system 11 may move simultaneously in the direction opposite to the stage. This enables quick detachment of the dummy panel DP from the dummy panel support portion DPS.

The dummy panel DP detached from the dummy panel support portion DPS by the dummy panel removal system 11 including the plurality of dummy panel removal devices 10 may be placed or stored in a separate dummy storage portion for disposal. In an embodiment, for example, the dummy storage portion may be positioned below the dummy panel removal system 11. The dummy panel removal system 11 may place the dummy panel DP in the dummy storage portion by releasing the gripped dummy panel DP.

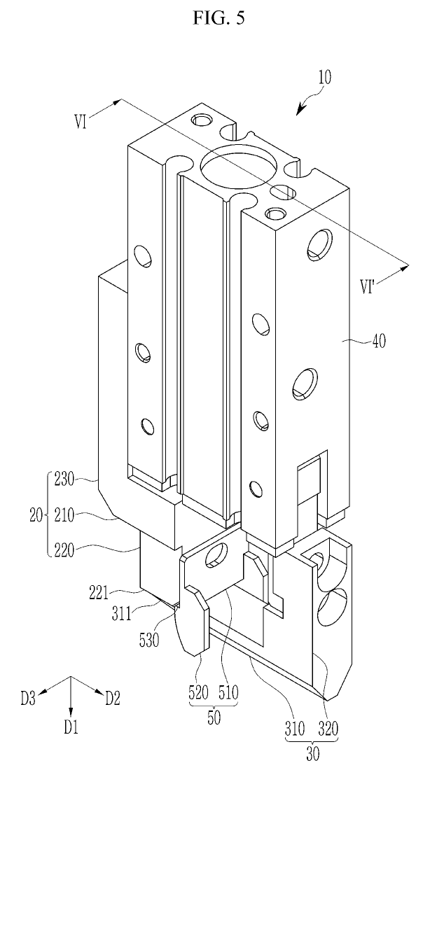

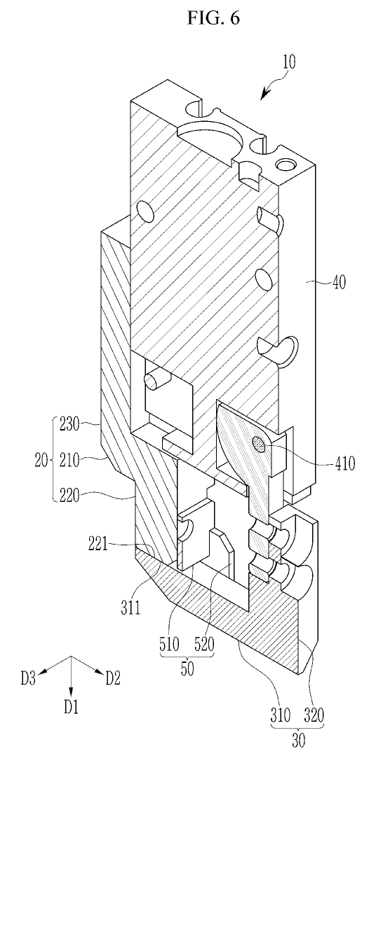

Hereinafter, the configuration of a dummy panel removal device according to an embodiment will be described in detail with reference to FIGS. 5 and 6. FIG. 5 is a view illustrating a dummy panel removal device according to an embodiment. FIG. 6 is a cross-sectional view taken along line VI-VI' of FIG. 5.

In an embodiment, the dummy panel removal device 10 may include a dummy block 20, a grip portion 30, a catching portion 50, and a body portion 40.

The dummy block 20 may include a rigid material. The dummy block 20 may include a first surface 221 facing a first direction D1 and configured to contact a first side of the dummy panel DP. The first surface 221 may face the first side of the dummy panel DP. The first surface 221 may have a flat shape.

The dummy block 20 may include a block center portion 210 extending in a second direction D2 intersecting the first direction D1, and a first block extension portion 220 and a second block extension portion 230 extending in opposite directions along the first direction D1 from both opposing ends of the block center portion 210 in the second direction D2. The first surface 221 of the dummy block 20 may be formed or defined at an end of the first block extension portion 220 in the first direction D1. The overall size of the dummy panel removal device 10 may be adjusted by adjusting the extension length of the block center portion 210 in the second direction D2 or the extension lengths of the first block extension portion 220 and second block extension portion 230 in the first direction D1.

The grip portion 30 may be positioned to face the dummy block 20 and include a second surface 311 configured to contact either the first surface 221 of the dummy block 20 or contact a second side of the dummy panel DP opposite to the first side. The grip portion 30 may be arranged with the dummy block 20 in the second direction D2.

The grip portion 30 may grip or release the dummy panel DP together with the dummy block 20. The dummy panel removal device 10 may grip or release the dummy panel as the grip portion 30 moves to bring the second surface 311 closer to or farther from the first surface 221 of the dummy block 20. The grip portion 30 may rotate about a rotation axis 410.

In a state where the first surface 221 and the second surface 311 are in contact with each other, the grip portion 30 may include a first grip extension portion 310 extending in the second direction D2, and a second grip extension portion 320 extending in the first direction D1 from an end of the first grip extension portion 310 in the second direction D2.

The second surface 311 of the grip portion 30 may be formed on the first grip extension portion 310. The second surface 311 may face the first direction D1.

In a state where the first surface 221 and second surface 311 are in contact with each other, the first grip extension portion 310 may have a shape extending in the second direction D2. In a state where the first surface 221 and second surface 311 are in contact with each other, when the grip portion 30 is rotated to its maximum position, the first grip extension portion 310 may have a shape extending in the first direction D1. The length of the first grip extension portion 310 in a third direction D3 may be smaller than the length of the first block extension portion 220 in the third direction D3.

A portion of the grip portion 30 may be accommodated in the body portion 40. In an embodiment, for example, a portion of the second grip extension portion 320 of the grip portion 30 may be accommodated in the body portion 40. Also, the rotation axis 410 forming the center of rotation motion of the grip portion 30 may be accommodated in the body portion 40. The rotation axis 410 may overlap with the body portion 40 and the second grip extension portion 320. As the grip portion 30 pivots about the rotation axis 410, the grip portion 30 may contact or separate from the dummy block 20. That is, the first surface 221 of the dummy block 20 and the second surface 311 of the grip portion 30 may move closer to or farther from each other according to the rotation of the grip portion 30.

The catching portion 50 may be positioned adjacent to the dummy block 20. The catching portion 50 may be arranged along the second direction D2 with the dummy block 20. The catching portion 50 may be positioned between the dummy block 20 and the grip portion 30. In an embodiment, for example, the catching portion 50 may be fixed to the dummy block 20.

The catching portion 50 may include a catching center portion 510 and a catching extension portion 520.

The catching center portion 510 may have a surface facing the second direction D2. Also, the catching center portion 510 may be fixed to the dummy block 20. The catching center portion 510 may be positioned adjacent to the dummy block 20. Also, the catching center portion 510 may contact the dummy block 20. The catching center portion 510 may be connected and fixed to the dummy block 20. The catching center portion 510 may be positioned between the dummy block 20 and the grip portion 30 along the second direction D2.

The catching extension portion 520 may be a portion extending in the first direction D1 from the catching center portion 510. In an embodiment, for example, the catching extension portion 520 may extend in the first direction D1 from an end of the catching center portion 510 in the third direction D3. The catching extension portion 520 may include a pair of extensions extending in the first direction D1 from both opposing ends of the catching center portion 510 in the third direction D3. A distance by which the pair of extensions are spaced apart in the third direction D3 may be greater than the length of the first grip extension portion 310 in the third direction D3. The first grip extension portion 310 rotating about the rotation axis 410 may move while passing between the pair of extensions. That is, the first grip extension portion 310 may use the space between the pair of extensions as its rotation path. In a state where the first surface 221 and second surface 311 are in contact with each other, the first grip extension portion 310 of the grip portion 30 may be positioned between the pair of extensions while simultaneously contacting the dummy block 20.

The catching extension portion 520 may protrude more in the first direction D1 than the first surface 221. In a state where the second surface 311 of the grip portion 30 contacts the first surface 221 of the dummy block 20 or the second side of the dummy panel, when viewed in the third direction D3 intersecting both the first direction D1 and the second direction D2, the first grip extension portion 310 may cross over the catching extension portion 520 in the second direction D2. That is, when the dummy panel removal device 10 is gripping the dummy panel DP, the first grip extension portion 310 may extend in the second direction D2 while the catching extension portion 520 extends in the first direction D1.

The catching extension portion 520 may include a protrusion 530 protruding from the catching center portion 510 toward the dummy block 20. When viewing the catching extension portion 520 in the third direction D3, the protrusion 530 may appear as a step shape. The protrusion 530 located on the catching extension portion 520 may serve as a position reference for assembling the catching portion 50 and the dummy block 20. The protrusion 530 located on the catching extension portion 520 may serve as a position reference for assembly by engaging with the edge of the dummy block 20.

The body portion 40 may serve to support the dummy block 20. Also, the body portion 40 may serve to support the grip portion 30. The body portion 40 may be arranged with the dummy block 20 along the second direction D2. The dummy block 20 may be fixed to one side surface of the body portion 40. The body portion 40 may be directly connected to the dummy block 20 or the grip portion 30, or the body portion 40 may be indirectly connected to and support the dummy block 20 or the grip portion 30.

Also, the body portion 40 may be configured to accommodate a portion of the grip portion 30 and a rotation axis 410, and to provide driving force for pivoting the grip portion 30 about the rotation axis 410. The driving force provided from the body portion 40 may be transmitted to the rotation axis 410 and rotate the grip portion 30 about the rotation axis 410. According to the rotation of the grip portion 30, the dummy panel removal device 10 may grip or release the dummy panel.

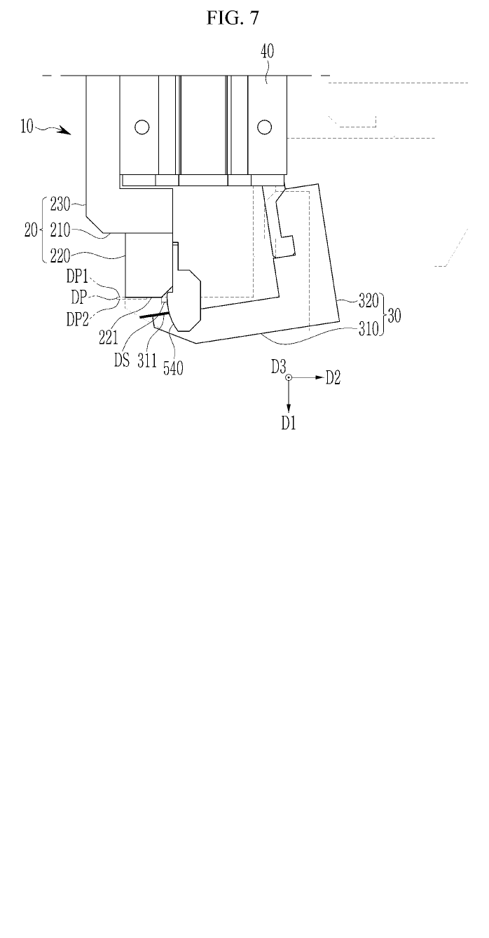

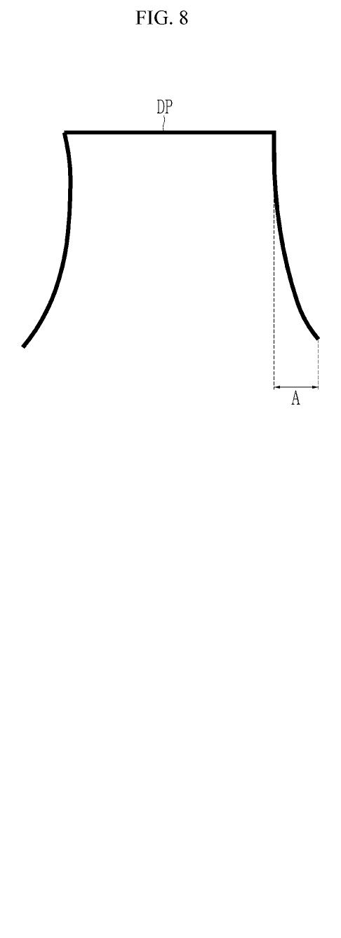

Hereinafter, the process of removing a dummy panel by a dummy panel removal device according to an embodiment will be described with reference to FIGS. 7 and 8. FIG. 7 is a side view illustrating a pivot operation of the grip portion of a dummy panel removal device according to an embodiment. FIG. 8 is a plan view illustrating a dummy panel in an elastically deformed state.

In an embodiment, the dummy panel removal device 10 may contact the first surface 221 of the dummy block 20 with the first side DP1 of the dummy panel DP while the first surface 221 and second surface 311 are separated or spaced apart from each other. Then, the grip portion 30 may be rotated clockwise so that the second surface 311 of the grip portion 30 contacts the second side DP2 of the dummy panel DP. In this way, the dummy panel removal device 10 may grip the dummy panel DP. After the dummy panel removal device 10 grips the dummy panel DP, the dummy panel DP may be detached from the dummy panel support portion by moving the dummy panel removal device 10 in a direction opposite to the dummy panel support portion DSP or the stage ST. Referring to FIG. 7, to detach the dummy panel DP from the dummy panel support portion, the dummy panel removal device 10 may rise while gripping the dummy panel DP. After the dummy panel DP is detached from the dummy panel support portion, the dummy panel removal device 10 may rotate the grip portion 30 counterclockwise to remove or release the dummy panel DP therefrom to be placed in the dummy storage portion for disposal. In an embodiment, for example, the dummy panel removal device 10 may drop the dummy panel DP into the dummy storage portion. The first surface 221 and the second surface 311 may be separated from each other for the dummy panel removal device 10 to remove or release the dummy panel DP therefrom.

In a state where the first surface 221 of the dummy block 20 and second surface 311 of the grip portion 30 are in contact with each other, the first block extension portion 220 of the dummy block 20 and the first grip extension portion 310 of the grip portion 30 may extend in directions perpendicular to each other. Also, when the grip portion 30 rotates counterclockwise from the state where the first surface 221 and the second surface 311 are in contact with each other, causing the second grip extension portion 320 to extend in the second direction D2, the first grip extension portion 310 and the first block extension portion 220 may extend parallel to each other.

In the process of separating the display panel PN and dummy panel DP by laser irradiation, an adhesive may be applied to the second side DP2 of the dummy panel DP to restrict movement of the display panel PN and dummy panel DP. Due to the adhesive applied to the second side DP2 of the dummy panel DP, it may be difficult to remove the dummy panel DP from the dummy panel removal device 10. For example, the adhesive applied to the second side DP2 of the dummy panel DP may stick to the second surface 311 or first grip extension portion 310 of the grip portion 30. Because the dummy panel DP includes a second side DP2 having adhesiveness, it may be difficult to remove the dummy panel DP from the dummy panel removal device 10. The dummy panel removal device 10 with the dummy panel DP stuck to it may not be able to easily perform subsequent dummy panel DP removal or release processes. Also, the dummy panel DP stuck to the dummy panel removal device 10 may interfere with the electronic device manufacturing process.

By positioning the catching portion 50 including the catching extension portion 520 between the dummy block 20 and the grip portion 30, the dummy panel DP may be easily removed from the dummy panel removal device 10. The catching portion 50 may be fixed to and connected to the dummy block 20. The catching extension portion 520 may extend in the first direction D1. The catching extension portion 520 may have a shape protruding in the first direction D1 based on the first surface 221. The extension length of the catching extension portion 520 in the first direction D1 is not limited.

When rotating the grip portion 30 counterclockwise to remove or release the dummy panel DP from the dummy panel removal device 10, the dummy panel DP may rotate together with the grip portion 30 while stuck to the second surface 311 of the grip portion 30.

While the grip portion 30 is rotating counterclockwise to remove the dummy panel DP from the dummy panel removal device 10, the dummy panel DP hits against the catching extension portion of the catching portion. Since the catching extension portion extends along the first direction D1 from the third direction D3 end of the catching center portion, the first grip extension portion 310 does not collide with the catching extension portion. This allows the first grip extension portion 310 to continue rotating counterclockwise, while the dummy panel DP gets caught on the catching extension portion of the catching portion and its movement becomes restricted.

The dummy panel DP may be detached from the first grip extension portion 310 of the grip portion 30 by the catching extension portion of the catching portion. This allows even a dummy panel DP having adhesiveness on its second side DP2 to be easily removed from the dummy panel removal device 10.

The dummy panel DP may be an elastic body whose shape may be deformed. FIG. 8 shows a plan view of a deformed dummy panel DP. When an external force is applied to a part of the dummy panel DP, the shape of the dummy panel DP may be deformed. For example, the external force applied to a part of the dummy panel DP may be a pulling force. FIG. 8 shows a dummy panel DP whose straight shape is deformed into a curved shape by an external force applied to a part thereof. FIG. 8 shows the shape of the dummy panel DP whose end portion has moved by distance A.

A deformed dummy panel DP may interfere with the operation of other electronic device manufacturing apparatus or electronic device manufacturing equipment located outside the dummy panel removal device 10. Alternatively, the entire deformed dummy panel DP may not fit into the dummy storage portion, and a part of the dummy panel DP may protrude outside the dummy storage portion. When a part of the dummy panel DP protrudes outside the dummy storage portion, it may also interfere with the operation of other electronic device manufacturing apparatus or electronic device manufacturing equipment. Therefore, it is desirable for the dummy panel removal device 10 to remove the dummy panel DP without deforming its shape.

The closer the first surface 221 formed on the dummy block 20 and the catching extension portion of the catching portion are positioned, the easier it may be to remove the dummy panel DP from the dummy panel removal device 10. The closer the first surface 221 and catching extension portion are positioned, the earlier the dummy panel DP may get caught by the catching extension portion with less rotation of the grip portion 30. When the dummy panel DP moves together with the rotation of the first grip extension portion 310 while stuck to it, the dummy panel DP may continue to receive force and its shape may become deformed. If the first surface 221 and catching extension portion are positioned close together, the deformation of the dummy panel DP's shape by rotation of the first grip extension portion 310 may be minimized. In other words, to remove the dummy panel DP from the dummy panel removal device 10 while minimizing deformation of the dummy panel DP's shape, it may be desired for the first surface 221 formed on the dummy block 20 and the catching extension portion of the catching portion 50 to be positioned close together.

In an embodiment, to minimize shape changes of the dummy panel DP, a spacing distance DS between the first surface 221 and the collision edge 540 of the catching extension portion in the second direction D2 may be equal to or less than one-fifth of the length of the first surface 221 in the second direction D2.

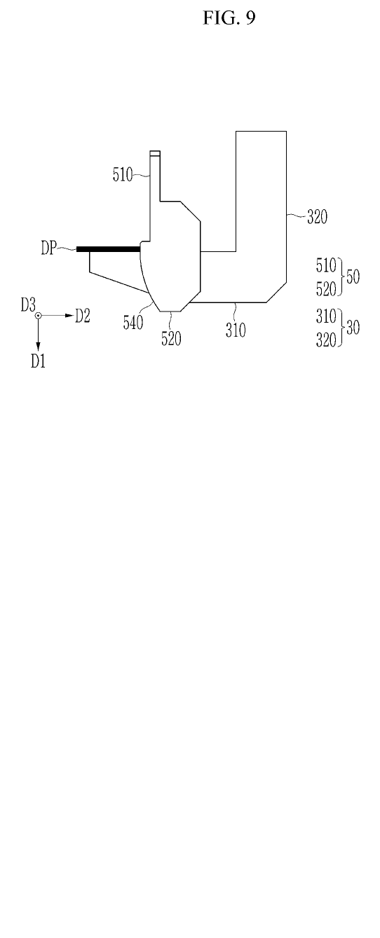

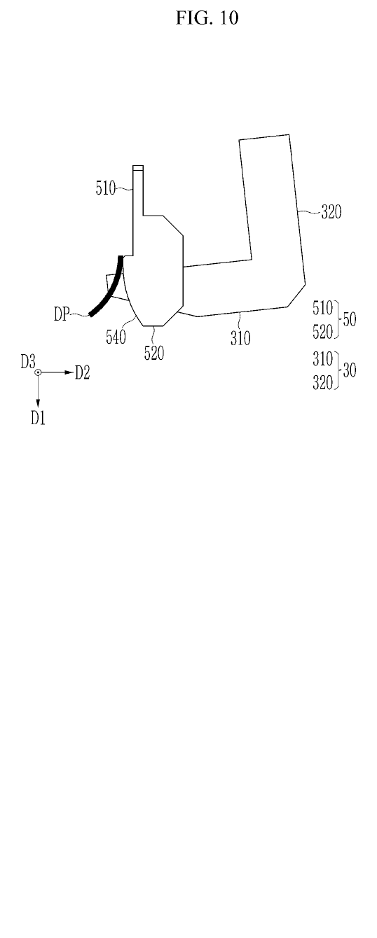

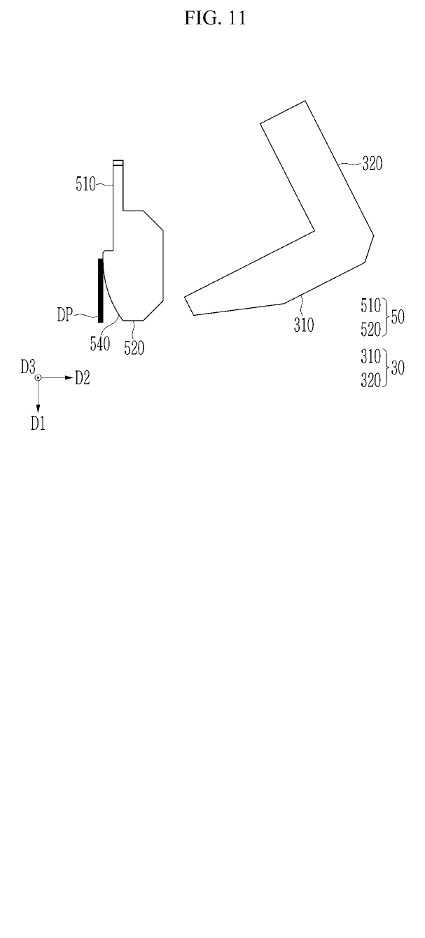

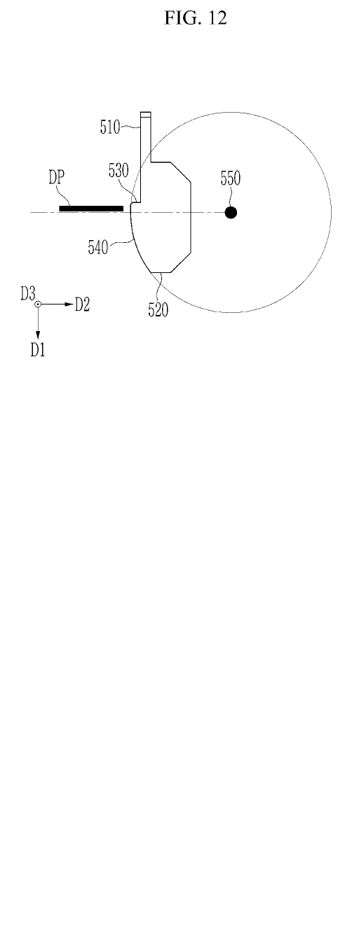

Hereinafter, a structure that allows easy detachment of the dummy panel from the catching extension portion will be described with reference to FIGS. 9 to 12. In FIGS. 9 to 12, configurations other than the grip portion 30 and catching portion 50 of the dummy panel removal device are omitted for clarity of illustration. FIG. 9 is a view illustrating a state where the first grip extension portion and the dummy panel are adhered. FIG. 10 is a view illustrating a process of transferring the dummy panel from the first grip extension portion to the catching extension portion. FIG. 11 is a view illustrating a state where the dummy panel is adhered to the catching extension portion. FIG. 12 is a side view illustrating a shape of the catching portion.

The adhesion between the second side DP2 of the dummy panel DP and the second surface 311 of the first grip extension portion 310 may be easily removed using the catching extension portion 520 of the catching portion 50. However, in the process of removing the dummy panel DP from the first grip extension portion 310 using the catching extension portion 520, the second side DP2 of the dummy panel DP may stick to the catching extension portion 520.

In an embodiment, the shape of the catching extension portion 520 may be defined to prevent the dummy panel DP from sticking to the catching extension portion 520. In an embodiment, for example, a collision edge 540 of the catching extension portion 520 adjacent to the first surface of the dummy block may have a curved shape. This way, since collision occurs only at one point between the dummy panel DP and the catching extension portion 520, the dummy panel DP may easily move to the dummy storage portion without sticking to the catching extension portion 520.

The collision edge 540 of the catching extension portion 520 that is adjacent to the first surface of the dummy block 20 and formed in a curved shape may be a portion facing the dummy panel DP. Also, the collision edge 540 of the catching extension portion 520 that is adjacent to the first surface of the dummy block 20 and formed in a curved shape may be a portion that collides with the dummy panel DP as the grip portion 30 rotates counterclockwise.

The collision edge 540 of the catching extension portion 520 that is adjacent to the first surface of the dummy block and formed in a curved shape may be an arc shape. One end of the collision edge 540 may form a protrusion 530.

When the dummy panel removal device is gripping the dummy panel DP, the spacing distance in the second direction D2 between the center of curvature 550 and the collision edge 540 may be less than the spacing distance in the second direction D2 between the center of curvature 550 and the dummy panel DP. That is, referring to FIG. 12, the center of curvature 550 may be positioned to the right of the dummy panel DP. Also, when the dummy panel removal device is gripping the dummy panel DP, the spacing distance in the first direction D1 between the center of curvature 550 and the body portion 40 may be greater than the spacing distance in the first direction D1 between the dummy panel DP and the body portion 40. That is, referring to FIG. 12, the center of curvature 550 may be positioned below the dummy panel DP. Alternatively, when the dummy panel removal device is gripping the dummy panel DP, the spacing distance in the first direction D1 between the center of curvature 550 and the body portion 40 may be approximately equal to the spacing distance in the first direction D1 between the dummy panel DP and the body portion 40. That is, referring to FIG. 12, the center of curvature 550 may be positioned slightly above or slightly below the dummy panel DP.

In an embodiment, the catching portion 50 may include an anti-adhesion coating to prevent the dummy panel DP from adhering to the catching portion 50. In an embodiment, for example, the anti-adhesion coating may be applied to the entire surface or a portion of the surface of the catching portion 50.

In an embodiment, the grip portion 30 may include an anti-adhesion coating on the second surface 311 to prevent the dummy panel DP from adhering to the grip portion 30. In an embodiment, for example, the anti-adhesion coating may be applied to the entire surface or a portion of the surface of the grip portion 30.

The anti-adhesion coating may be a coating that may effectively prevent adhesion between the dummy panel DP and the catching portion 50 or between the dummy panel DP and the grip portion 30. The anti-adhesion coating is not limited. In an embodiment, for example, the anti-adhesion coating may be a tack free coating. The tack free coating may be a coating that has no adhesiveness after curing. The anti-adhesion coating may include silicone, urethane, or epoxy.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A dummy panel removal device comprising:
a dummy block including a first surface facing a first direction, wherein the first surface of the dummy block contacts a first side of a dummy panel;
a grip portion positioned to face the dummy block and including a second surface facing the first surface of the dummy block with the dummy panel interposed between the dummy block and the grip portion; and
a catching portion fixed to the dummy block between the dummy block and the grip portion,
wherein the catching portion includes a catching extension portion protruding more in the first direction than the first surface of the dummy block.

2. The dummy panel removal device of claim 1, further comprising:
a body portion including the dummy block fixed to one side surface of the body portion.

3. The dummy panel removal device of claim 2, wherein
the body portion accommodates a portion of the grip portion and a rotation axis, and provides a driving force for pivoting the grip portion about the rotation axis.

4. The dummy panel removal device of claim 1, wherein the dummy block comprises:
a block center portion extending in a second direction intersecting the first direction; and
a first block extension portion and a second block extension portion extending in opposite directions along the first direction respectively from both opposing ends of the block center portion in the second direction,
wherein the first surface of the dummy block is at an end of the first block extension portion in the first direction.

5. The dummy panel removal device of claim 1, wherein the grip portion comprises:
a first grip extension portion extending in a second direction intersecting the first direction; and
a second grip extension portion extending in the first direction from an end of the first grip extension portion in the second direction.

6. The dummy panel removal device of claim 5, wherein
the second surface of the grip portion is a surface of the first grip extension portion.

7. The dummy panel removal device of claim 5, wherein
in a state where the second surface of the grip portion faces the first surface of the dummy block with the dummy panel interposed between the dummy block and the grip portion, the first grip extension portion crosses over the catching extension portion in the second direction when viewed in a third direction intersecting both the first direction and the second direction.

8. The dummy panel removal device of claim 1, wherein
the catching portion further includes a catching center portion including a surface facing a second direction intersecting the first direction and fixed to the dummy block, and
the catching extension portion extends in the first direction from an end of the catching center portion in a third direction intersecting both the first direction and the second direction.

9. The dummy panel removal device of claim 8, wherein
the catching extension portion comprises a pair of extensions extending in the first direction respectively from both opposing ends of the catching center portion in the third direction, and
a distance between the pair of extensions in the third direction is greater than a length of the grip portion in the third direction.

10. The dummy panel removal device of claim 8, wherein
the catching extension portion includes a protrusion protruding from the catching center portion toward the dummy block.

11. The dummy panel removal device of claim 1, wherein
a collision edge of the catching extension portion adjacent to the first surface of the dummy block has a curved shape.

12. The dummy panel removal device of claim 11, wherein
the curved shape is an arc shape.

13. The dummy panel removal device of claim 11, wherein
the first surface of the dummy block and the collision edge are spaced apart in a second direction intersecting the first direction, and
a spacing distance between the first surface of the dummy block and the collision edge in the second direction is equal to or less than one-fifth of a length of the first surface of the dummy block in the second direction.

14. The dummy panel removal device of claim 1, wherein
an anti-adhesion coating is coated on the second surface of the grip portion.

15. The dummy panel removal device of claim 1, wherein
an anti-adhesion coating is coated on the catching portion.

16. A dummy panel removal system comprising:
a plurality of dummy panel removal devices,
wherein each of the plurality of dummy panel removal devices includes:
a dummy block including a first surface facing a first direction, wherein the first surface of the dummy block contacts a first side of a dummy panel;
a grip portion positioned to face the dummy block and including a second surface facing the first surface of the dummy block with the dummy panel interposed between the dummy block and the grip portion; and
a catching portion fixed to the dummy block between the dummy block and the grip portion,
wherein the catching portion includes a catching extension portion protruding more in the first direction than the first surface of the dummy block, and
wherein the plurality of dummy panel removal devices are arranged along an extension direction of the dummy panel.

17. The dummy panel removal system of claim 16, wherein
in a state where the second surface of the grip portion faces the first surface of the dummy block with the dummy panel interposed between the dummy block and the grip portion, the grip portion crosses over the catching extension portion in a second direction intersecting the first direction when viewed in a third direction intersecting both the first direction and the second direction.

18. The dummy panel removal system of claim 16, wherein
the catching portion further includes a catching center portion including a surface facing a second direction intersecting the first direction and fixed to the dummy block, and
the catching extension portion extends in the first direction from an end of the catching center portion in a third direction intersecting both the first direction and the second direction.

19. The dummy panel removal system of claim 16, wherein
a collision edge of the catching extension portion adjacent to the first surface of the dummy block has a curved shape.

20. The dummy panel removal system of claim 19, wherein
the first surface of the dummy block and the collision edge are spaced apart in a second direction intersecting the first direction, and
a spacing distance between the first surface of the dummy block and the collision edge in the second direction is equal to or less than one-fifth of a length of the first surface of the dummy block in the second direction.
